(19) United States
(12) Patent Application Publication
(10) Pub. No.: US 2026/0348873 A1
(43) Pub. Date: Nov. 5, 2026

(54) OBSERVATION APPARATUS, OBSERVATION METHOD, AND SUBSTRATE PROCESSING APPARATUS

(71) Applicant: SCREEN Holdings Co., Ltd., Kyoto (JP)

(72) Inventor: Daisuke HISHITANI, Kyoto (JP)

(21) Appl. No.: 19/487,774

(22) PCT Filed: Apr. 3, 2024
(86) PCT No.: PCT/JP2024/013767

§ 371 Date: Nov. 25, 2025

(30) Foreign Application Priority Data
May 29, 2023 (JP) 2023-087515

(51) Int. Cl. G01N 21/95; G01N 21/88; G01N 21/956; H10P 72/00; H10P 72/76

(52) U.S. Cl. CPC G01N 21/9503; G01N 21/8806; G01N 21/956; H10P 72/0424; H10P 72/0606; H10P 72/7618; G01N 2021/95676

(57) ABSTRACT

An observation method, and a substrate processing apparatus, after light beams generated in a light source part are incident to an incident end of a beam homogenizer and light quantity distribution of the light beams is uniformized by the beam homogenizer, the light beams go out form an outgoing end of the beam homogenizer. Thus, the primary illumination light is formed of the light beams having a uniform light quantity distribution. Then, the outgoing end is projected on a diffusion surface by a projection optical part. Therefore, the diffusion surface is irradiated with the primary illumination light having a uniform light quantity distribution, and the secondary illumination light is emitted from the diffusion surface toward an observation target part. As a result, the observation target part is illuminated with the secondary illumination light having a uniform light quantity distribution.

### TECHNICAL FIELD BACKGROUND ART

This invention relates to an observation technique for observing an observation target such as a semiconductor wafer or the like, and more particularly to an observation technique suitable for observing an observation target part such as a peripheral edge part of a semiconductor wafer, or the like, and relates to a substrate processing apparatus using the observation technique.

The disclosure of Japanese Patent Application No. 2023-87515 filed on May 29, 2023 including specification, drawings and claims is incorporated herein by reference in its entirety.

### BACKGROUND ART

A processing system for performing various types of processing on a peripheral edge part of an object to be observed (observation target), such as a semiconductor wafer or the like, is well known. In Patent Literature 1, for example, after a coating material is applied and spread on a substrate, a bevel part of the substrate is cleaned. Further, after the bevel cleaning process (step), an inspection process (step) of observing a surface state of the bevel part, to thereby determine whether or not the coating material is left in the bevel part. This inspection process is performed by an apparatus different from the apparatus which performs the bevel cleaning process.

### CITATION LIST

### Patent Literature

Patent Literature 1: JP2017-139492A

### SUMMARY OF INVENTION

### Technical Problem

In a system disclosed in above-described Patent Literature 1, a substrate processing apparatus which performs the bevel cleaning process and an inspection apparatus which performs the inspection process are separated from each other. For this reason, there occurs a time lag between occurrence of a defect in the substrate processing apparatus and detection of the defect in the inspection apparatus. This sometimes causes a reduction in the yield.

Then, in order to solve the above-described problem, it is considered to incorporate an observation apparatus into the substrate processing apparatus. In the observation apparatus, however, a CMOS (Complementary Metal Oxide Semiconductor) camera is disposed in a peripheral edge part of a substrate and this camera observes the peripheral edge part of the substrate. Further, in a case of inspecting a surface state of a bevel part, a camera for observing the bevel part from various directions and a light source for illuminating the bevel part from various directions corresponding to the camera are needed. In short, the conventional observation apparatus has relatively large constituent elements disposed in the vicinity of the peripheral edge part of the substrate, and it is thereby difficult to incorporate the observation apparatus into the substrate processing apparatus.

This invention is intended to solve the above-described problem, and it is an object of the present invention to provide an observation apparatus and an observation method each capable of excellently observing an observation target part such as a peripheral edge part of a semiconductor wafer or the like and a substrate processing apparatus equipped with the observation apparatus.

### Solution to Problem

A first aspect of this invention is directed to an observation apparatus for observing an observation target part of an observation target. The apparatus includes: an illumination optical system configured to emit primary illumination light to the vicinity of the observation target part; a head unit having a diffusion surface which diffuses the primary illumination light in the vicinity of the observation target part and being configured to illuminate the observation target part by irradiating the observation target part with diffused light generated on the diffusion surface as secondary illumination light; and an observation optical system configured to receive reflected light reflected on the observation target part illuminated with the secondary illumination light to observe the observation target part, wherein the illumination optical system has: a beam homogenizer having an incident end and an outgoing end; a light source part configured to cause light beams forming the primary illumination light to be incident to the incident end of the beam homogenizer; and a projection optical part configured to project the outgoing end of the beam homogenizer onto the diffusion surface.

A second aspect of this invention is directed to an observation method for observing an observation target part of an observation target. The method includes: an illuminating step of illuminating the observation target part by emitting primary illumination light to a diffusion surface of a head unit positioned in the vicinity of the observation target part to thereby irradiate the observation target part with diffused light generated on the diffusion surface, as secondary illumination light; and an observing step of observing the observation target part by receiving reflected light reflected on the observation target part illuminated with the secondary illumination light, wherein the illuminating step has: a step of causing light beams forming the primary illumination light to be incident to a beam homogenizer; and a step of projecting an outgoing end of the beam homogenizer onto the diffusion surface.

A third aspect of this invention is directed to a substrate processing apparatus. The apparatus includes: a rotating mechanism configured to hold and rotate a substrate; a processing mechanism configured to process a peripheral edge part of the substrate rotated by the rotating mechanism by supplying a processing liquid to the peripheral edge part of the substrate; and an observation apparatus configured to observe the peripheral edge part before or after processing the peripheral edge part, wherein the observation apparatus includes: an illumination optical system configured to emit primary illumination light to the vicinity of the observation target part; a head unit having a diffusion surface which diffuses the primary illumination light in the vicinity of the observation target part and being configured to illuminate the observation target part by irradiating the observation target part with diffused light generated on the diffusion surface as secondary illumination light; and an observation optical system configured to receive reflected light reflected on the observation target part illuminated with the secondary illumination light to observe the observation target part, wherein the illumination optical system has: a beam homogenizer having an incident end and an outgoing end; a light source part configured to cause light beams forming the primary illumination light to be incident to the incident end of the beam homogenizer; and a projection optical part configured to project the outgoing end of the beam homogenizer onto the diffusion surface.

In the invention configured thus, the head unit is positioned in the vicinity of the observation target part. Then, by emitting the primary illumination light to the diffusion surface of the head unit, the observation target part is irradiated with the diffused light generated on the diffusion surface as the secondary illumination light. Thus, on the observation target part illuminated with the diffused light, part of the diffused light is reflected. Then, the reflected light is incident to the observation optical system, to thereby observe the observation target part.

Herein, in order to excellently observe the observation target part, it is important that the light quantity distribution of the secondary illumination light is uniform. Then, in the present invention, after the light beams generated in the light source part are incident to the incident end of the beam homogenizer and the light quantity distribution of the light beams is uniformized by the beam homogenizer, the light beams go out form the outgoing end of the beam homogenizer. Thus, the primary illumination light is formed of the light beams having a uniform light quantity distribution. Then, the outgoing end from which the primary illumination light goes out is projected on the diffusion surface by the projection optical part. Therefore, the diffusion surface is irradiated with the primary illumination light having a uniform light quantity distribution, and the secondary illumination light is emitted from the diffusion surface toward the observation target part. As a result, the observation target part is illuminated with the secondary illumination light having a uniform light quantity distribution.

### Advantageous Effects of Invention

According to this invention, it is possible to achieve an observation apparatus capable of excellently observing an observation target part of an observation target. Further, by using this observation apparatus, it becomes easier to incorporate the observation apparatus into a substrate processing apparatus.

All of a plurality of constituent elements of each aspect of the present invention described above are not essential and some of the plurality of constituent elements can be appropriately changed, deleted, replaced by other new constituent elements or have limited contents partially deleted in order to solve some or all of the aforementioned problems or to achieve some or all of effects described in this specification. Further, some or all of technical features included in one aspect of the present invention described above can be combined with some or all of technical features included in another aspect of the present invention described above to obtain one independent form of the present invention in order to solve some or all of the aforementioned problems or to achieve some or all of the effects described in this specification.

### BRIEF DESCRIPTION OF DRAWINGS

FIG. 1 A diagram showing a substrate processing system equipped with one embodiment of a substrate processing apparatus in accordance with the present invention.

FIG. 2 A diagram schematically showing a configuration of the substrate processing apparatus.

FIG. 3 A plan view of part of the substrate processing apparatus viewed from above.

FIG. 4 A a diagram exemplarily showing a shape of a peripheral edge part of a substrate to be imaged.

FIG. 5 A block diagram showing an electrical configuration of the substrate processing apparatus shown in FIGS. 2 and 3.

FIG. 6A A perspective view showing a head unit of an imaging mechanism.

FIG. 6B Another perspective view showing the head unit of the imaging mechanism.

FIG. 7A A view schematically showing how light contributing to upper surface imaging propagates.

FIG. 7B Another view schematically showing how the light contributing to the upper surface imaging propagates.

FIG. 8A A view schematically showing how light contributing to side surface imaging propagates.

FIG. 8B Another view schematically showing how the light contributing to the side surface imaging propagates.

FIG. 9 A chart schematically showing images of the peripheral edge part of the substrate captured by an imager.

FIG. 10 A diagram showing one example of an illumination optical system provided in the substrate processing apparatus in accordance with the present invention.

FIG. 11 A diagram showing one example of a drive circuit of light emitting elements.

FIG. 12 A diagram showing another example of the illumination optical system provided in the substrate processing apparatus in accordance with the present invention.

FIG. 13 A diagram showing still another example of the illumination optical system provided in the substrate processing apparatus in accordance with the present invention.

FIG. 14 A diagram showing another example of the drive circuit of the light emitting elements.

### DESCRIPTION OF EMBODIMENTS

FIG. 1 is a diagram showing a substrate processing system equipped with one embodiment of a substrate processing apparatus in accordance with the present invention. The substrate processing system 200 includes a substrate processing station 210 for processing a substrate S and an indexer station 220 coupled to this substrate processing station 210. The indexer station 220 includes a container holder 221 capable of holding a plurality of containers C (FOUPs (Front Opening Unified Pods), SMIF (Standard Mechanical Interface) pods, OCs (Open Cassettes), or the like for housing a plurality of substrates S in a sealed state) for housing the substrates S, and an indexer robot 222 for accessing the container C held by this container holder 221 to take out an unprocessed substrate S from the container C and house a processed substrate S into the container C. In each container C, a plurality of substrates S are housed substantially in a horizontal posture.

In the present specification, among both main surfaces of the substrate S, a pattern formation surface (one main surface) on which a pattern is formed is referred to as a “front surface” and the other main surface on the opposite side, on which no pattern is formed, is referred to as a “back surface”. Further, a surface facing down is referred to as a “lower surface” and another surface facing up is referred to as an “upper surface”. Furthermore, in the present specification, the “pattern formation surface” refers to a surface of the substrate on which a projection-depression pattern is formed in an arbitrary region.

The indexer robot 222 includes a base 222a fixed to an apparatus housing, an articulated arm 222b provided on the base 222a, rotatably about a vertical axis, and a hand 222c mounted on a tip of the articulated arm 222b. The hand 222c is structured such that the substrate S can be placed and held on an upper surface thereof. Such an indexer robot including the articulated arm and the hand for holding the substrate is well known and therefore will not be described in detail.

The substrate processing station 210 includes a substrate conveyor robot 211 arranged substantially in a center in a plan view and a plurality of processing units 1 arranged to surround this substrate conveyor robot 11. Specifically, the plurality of processing units 1 are arranged to face a space where the substrate conveyor robot 211 is arranged. Main constituent elements of the processing unit 1 are arranged inside a processing chamber 100. The substrate conveyor robot 211 timely accesses these processing units 1 to transfer the substrates S. On the other hand, each processing unit 1 performs predetermined processing on the substrate S. In the present embodiment, one of these processing units 1 corresponds to the substrate processing apparatus in accordance with the present invention.

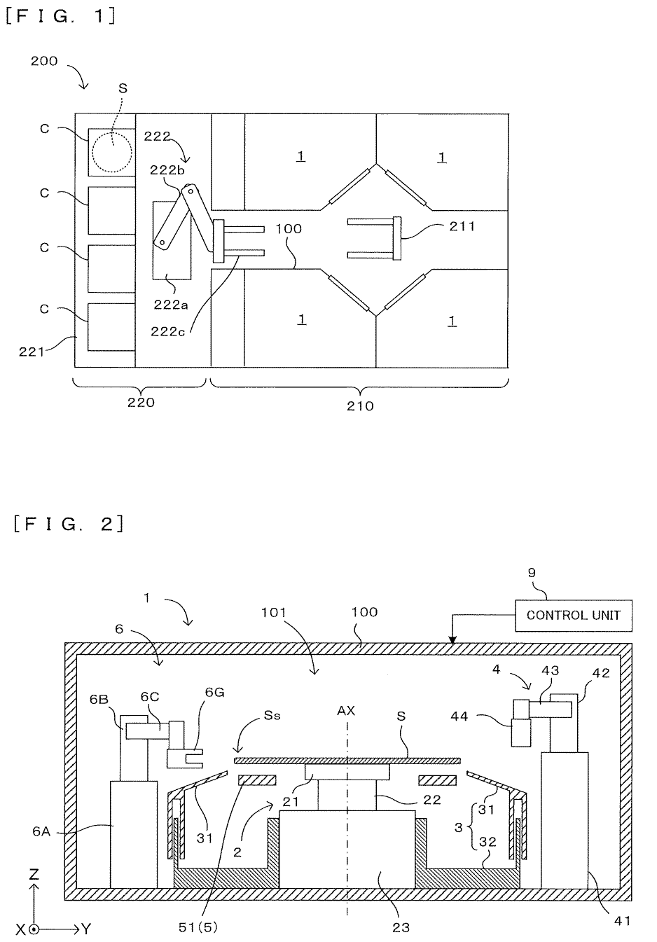

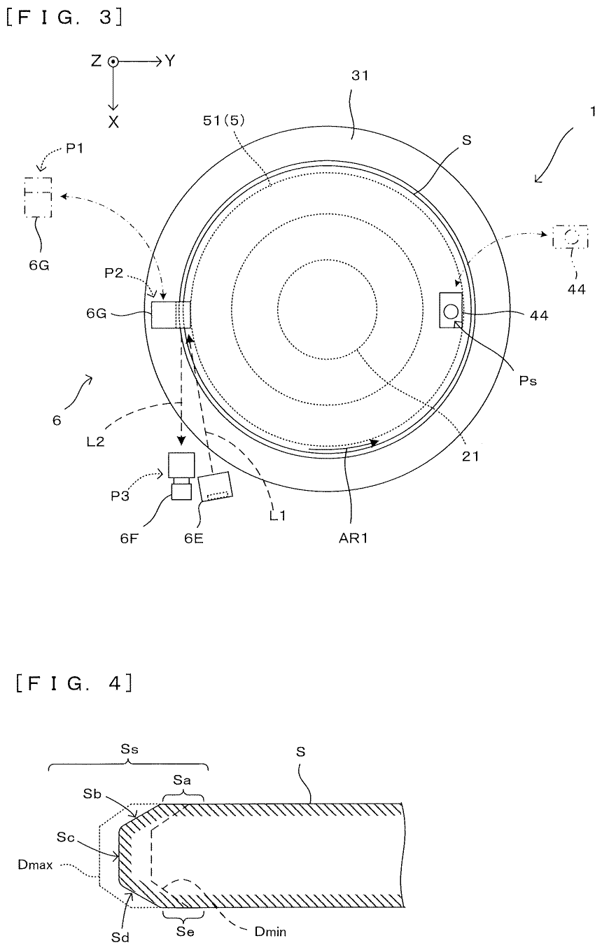

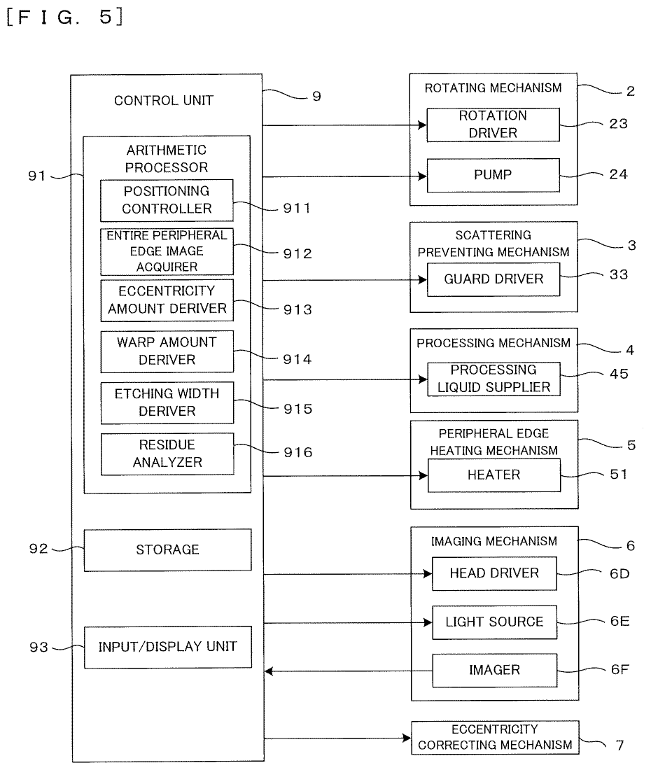

FIG. 2 is a diagram schematically showing a configuration of the substrate processing apparatus. FIG. 3 is a plan view of part of the substrate processing apparatus viewed from above. FIG. 4 is a diagram exemplarily showing a shape of a peripheral edge part of a substrate to be imaged. FIG. 5 is a block diagram showing an electrical configuration of the substrate processing apparatus shown in FIGS. 2 and 3. In FIGS. 2 and 3 and each figure to be referred to below, each component is sometimes shown with the dimensions and the number thereof exaggerated or simplified to facilitate understanding. Further, to clarify a directional relationship, a coordinate system in which a Z axis extends in a vertical direction and an XY plane is a horizontal plane is added as appropriate in each figure.

A substrate processing apparatus (processing unit) 1 is provided with a rotating mechanism 2, a scattering preventing mechanism 3, a processing mechanism 4, a peripheral edge heating mechanism 5, and an imaging mechanism 6. Each of these mechanisms 2 to 6 is housed in an internal space 101 of the processing chamber 100. Each of the mechanisms 2 to 6 is electrically connected to a control unit 9 for controlling the entire apparatus and operates in response to an instruction from the control unit 9.

As the control unit 9, for example, a unit like a general computer can be adopted Specifically, in the control unit 9, a CPU serving as an arithmetic processor 91 performs arithmetic processing, thereby controlling each component of the substrate processing apparatus 1. The substrate processing apparatus 1 thereby performs bevel etching processing by supplying a processing liquid to a peripheral edge part of an upper surface of the substrate S in the processing chamber. Furthermore, the detailed configuration and operation of the control unit 9 will be described in detail later. Further, although the control unit 9 is provided for each substrate processing apparatus 1 in the present embodiment, there may be a configuration where a plurality of substrate processing apparatuses 1 are controlled by one control unit. Furthermore, there may be another configuration where the substrate processing apparatus 1 is controlled by a control unit (not shown) for controlling the entire substrate processing system 200.

The rotating mechanism 2 rotates the substrate S in a rotational direction AR1 (FIG. 3) while holding the substrate S substantially in a horizontal posture with the surface of the substrate S facing up. The rotating mechanism 2 rotates the substrate S about a vertical axis of rotation AX passing through a center of the main surface of the substrate S. The rotating mechanism 2 includes a spin chuck 21, which is a disk-like member smaller than the substrate S. The spin chuck 21 is so provided that an upper surface thereof is substantially horizontal and a center axis thereof coincides with the axis of rotation AX. A rotary shaft 22 is coupled to a lower surface of the spin chuck 21. The rotary shaft 22 extends in a vertical direction with an axis thereof aligned with the axis of rotation AX. Further, a rotation driver (e.g., a motor) 23 is connected to the rotary shaft 22. The rotation driver 23 rotates and drives the rotary shaft 22 about the axis thereof in response to a rotation command from the control unit 9. Therefore, the spin chuck 21 is rotatable about the axis of rotation AX together with the rotary shaft 22. The rotation driver 23 and the rotary shaft 22 provide a function of rotating the spin chuck 21 about the axis of rotation AX.

An unillustrated through hole is provided in a central part of the spin chuck 21 and communicates with an internal space of the rotary shaft 22. A pump 24 (FIG. 5) is connected to the internal space via a pipe having a valve (not shown) disposed therein. The pump 24 and the valve are electrically connected to the control unit 9 and operate in response to a command from the control unit 9. A negative pressure and a positive pressure are thereby selectively applied to the spin chuck 21. For example, when the pump 24 applies the negative pressure to the spin chuck 21 with the substrate S placed substantially in a horizontal posture on the upper surface of the spin chuck 21, the spin chuck 21 sucks and holds the substrate S from below. On the other hand, when the pump 24 applies the positive pressure to the spin chuck 21, the substrate S becomes removable from the upper surface of the spin chuck 21. Further, when the suction of the pump 24 is stopped, the substrate S becomes horizontally movable on the upper surface of the spin chuck 21.

The scattering preventing mechanism 3 includes a substantially tubular cup 31 provided to surround an outer periphery of the substrate S held on the spin chuck 21 as shown in FIGS. 2 and 3 and a liquid receiver 32 provided below an outer peripheral part of the cup 31. A guard driver 33 (FIG. 5) operates in response to a control command from the control unit 9, whereby the cup 31 is raised and lowered. When the cup 31 is positioned at a lower position, an upper end part of the cup 31 is located below a peripheral edge part Ss of the substrate S held on the spin chuck 21 as shown in FIG. 2. Conversely, when the cup 31 is positioned at an upper position, the upper end part of the cup 31 is located above the peripheral edge part Ss of the substrate S.

When the cup 31 is located at the lower position, the substrate S held on the spin chuck 21 is exposed to the outside of the cup 31 as shown in FIG. 2. This prevents the cup 31 from becoming a hindrance, for example, when the substrate S is carried into and from the spin chuck 21.

On the other hand, when the cup 31 is located at the upper position, an inner peripheral surface of the cup 31 surrounds the outer periphery of the substrate S held on the spin chuck 21. It is thereby possible to prevent droplets of the processing liquid shaken off from the peripheral edge part Ss of the substrate S during the bevel etching processing described later from being scattered in the processing chamber 100. Further, it becomes possible to reliably collect the processing liquid. Specifically, the droplets of the processing liquid shaken off from the peripheral edge part Ss of the substrate S by the rotation of the substrate S adhere to the inner peripheral surface of the cup 31, flow down and are gathered and collected by the liquid receiver 32 arranged below the cup 31.

The processing mechanism 4 includes a base 41, a pivot shaft 42, an arm 43, and a processing liquid nozzle 44. The base 41 is fixed to the processing chamber 100. The pivot shaft 42 is freely rotatably provided on this base 41. The arm 43 horizontally extends from the pivot shaft 42, and the processing liquid nozzle 44 is attached to a tip of the arm 43. The pivot shaft 42 turns in response to a control command from the control unit 9, whereby the arm 43 swings. The processing liquid nozzle 44 on the tip of the arm 43 thereby moves between a retracted position where the processing liquid nozzle 44 is retracted laterally from above the substrate S to the side thereof and a processing position above the peripheral edge part of the substrate S. FIG. 3 shows a state indicated by the two-dot chain line, where the nozzle 44 is located at the retracted position and another state indicated by the solid line, where the nozzle 44 is located at the processing position.

The processing liquid nozzle 44 is connected to a processing liquid supplier 45 (FIG. 5). Then, when the processing liquid supplier 45 supplies the processing liquid toward the processing liquid nozzle 44 in response to a supply command from the control unit 9, the processing liquid is discharged from the processing liquid nozzle 44 toward a processing start position Ps. This processing start position Ps is one point on a movement path of the peripheral edge part Ss of the substrate S. Accordingly, the spin chuck 21 rotates while the processing liquid nozzle 44 is discharging the processing liquid, whereby each part of the peripheral edge part Ss of the substrate S receives the supply of the processing liquid while passing through the processing start position Ps. As a result, the bevel etching processing is performed by using the processing liquid on the entire peripheral edge part Ss of the substrate S.

The peripheral edge heating mechanism 5 is provided with an annular heater 51. The heater 51 includes a built-in heating element extending in a circumferential direction of the substrate S along a peripheral edge part of the lower surface of the substrate S. When a heating command is given to this heater 51 from the control unit 9, the peripheral edge part Ss of the substrate S is heated from below by heat released from the heating element. The temperature of the peripheral edge part Ss thereby increases to a value suitable for the bevel etching processing.

The imaging mechanism 6 includes a base 6A, a pivot shaft 6B, an arm 6C, a head driver 6D, a light source 6E, an imager 6F and a head unit 6G. The base 6A is fixed to the processing chamber 100. The pivot shaft 6B is freely rotatably provided on this base 6A. The arm 6C horizontally extends from the pivot shaft 6B, and the head unit 6G is attached to a tip of the arm 6C. Then, when a control command from the control unit 9 is given to the head driver 6D (FIG. 5) for driving the arm 6C, the head driver 6D swings the arm 6C in response to this command. As shown by the one-dot chain line in FIG. 3, the head unit 6G attached to the tip of the arm 6C reciprocates between a retracted position P1 where the head unit 6G is retracted laterally from above the substrate S to the side thereof and an imaging position P2 where the peripheral edge part Ss of the substrate S is imaged. FIG. 3 shows a state indicated by the one-dot chain line, where the head unit 6G is located at the retracted position and another state indicated by the solid line, where the head unit 6G is located at the imaging position. At the imaging position P2, the head unit 6G is disposed in proximity to an end part of the substrate S on the (−Y) side.

As shown in FIG. 3, an illumination optical system 6E and an observation optical system 6F are provided at a separated position P3 separated from the imaging position P2 in an X direction. This separated position P3 is separated from the substrate S and the respective components (the rotating mechanism 2, the scattering preventing mechanism 3, the processing mechanism 4, and the peripheral edge heating mechanism 5) for performing the bevel etching processing, such as the cup 31 and the like. The illumination optical system 6E emits illumination light L1 toward the imaging position P2 from the outside of the cup 31. At this time, the cup 31 is positioned at the lower position, the head unit 6G is positioned at the imaging position P2, and the illumination light L1 enters the head unit 6G. This illumination light L1 is diffusely reflected on the head unit 6G. The peripheral edge part Ss of the substrate S is illuminated with diffused light generated in this way. Then, reflected light L2 reflected on the peripheral edge part Ss of the substrate S is further reflected on the head unit 6G. The reflected light L2 is guided toward the separated position P3 from the head unit 6G and enters the observation optical system 6F. The observation optical system 6F thereby acquires an image of the peripheral edge part Ss of the substrate S and sends image data thereof to the control unit 9.

Herein, the peripheral edge part Ss of the substrate S to be imaged in the present embodiment will be described with reference to FIG. 4. As shown in FIG. 4, the substrate S such as a semiconductor wafer or the like sometimes has a bevel part having an inclined surface, which is formed at the peripheral edge part thereof. The “bevel part” described herein refers to an entire region in a state where a surface of the substrate S is inclined with respect to a horizontal plane when the substrate S is in a horizontal posture.

As to the cross-sectional shape and the dimensions of the bevel part, maximum dimensions Dmax indicated by the dotted line in this figure and minimum dimensions Dmin indicated by the broken line are defined as standards, and as long as the dimensions thereof fall into this range, generally, relatively high degree of freedom is given thereto. There are many cases where the cross section of the bevel part is constituted of a plurality of planes having different tilts as shown in FIG. 4, but there are some cases where the bevel part is constituted of a continuous curved plane.

Hereinafter, if necessary, a portion in the peripheral edge part Ss of the substrate S, which is the same plane as the upper surface of the substrate S, is referred to as an “A surface” and represented by a reference sign “Sa” and an end surface of the substrate S is referred to as a “C surface” and represented by a reference sign “Sc”. Then, an inclined surface connecting the A surface Sa and the C surface Sc is referred to as a “B surface” and represented by a reference sign “Sb”. Further, another portion which is the same plane as the lower surface of the substrate S is referred to as an “E surface” and represented by a reference sign “Se” and an inclined surface connecting the C surface Sc and the E surface Se is referred to as a “D surface” and represented by a reference sign “Sd”. The “peripheral edge part Ss” in the present specification is a concept which comprehensively includes these planes.

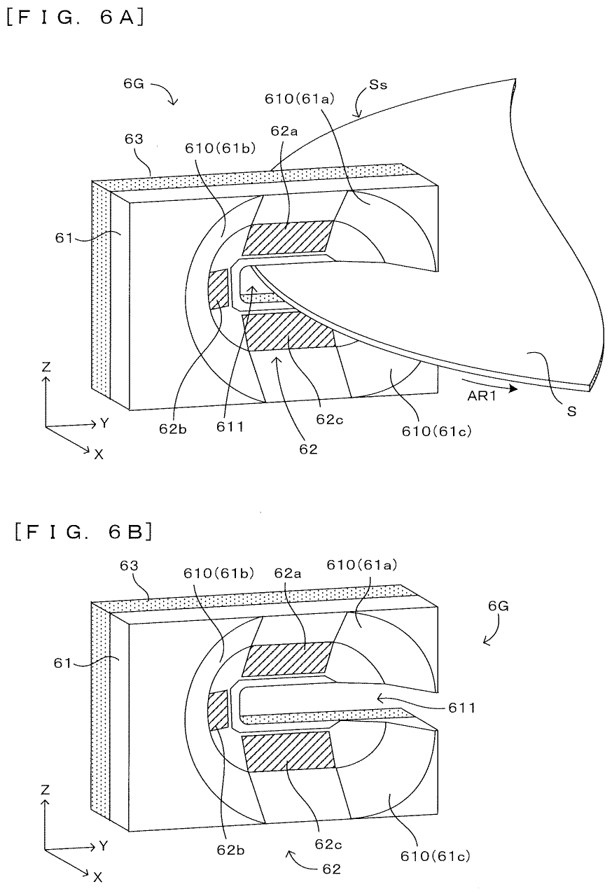

As described above, the head unit 6G includes both a diffused illumination function of receiving the illumination light L1 from the illumination optical system 6E to generate the diffused light and illuminating the peripheral edge part Ss of the substrate S with the diffused light and a guide function of guiding the reflected light L2 reflected on the peripheral edge part Ss to the observation optical system 6F. The configuration and operation of the head unit 6G will be described below with reference to FIGS. 6 to 9. After that, the configuration and operation of the illumination optical system 6E will be described in detail.

FIGS. 6A and 6B are perspective views each showing the head unit of the imaging mechanism. More specifically, FIG. 6A is a view showing a state where the head unit 6G is disposed at the imaging position P2, and FIG. 6B is a view showing a state where the substrate S is omitted from FIG. 6A. The head unit 6G has a diffused illuminator 61 having diffusion surfaces 610, a guide 62 consisting of three mirror members 62a to 62c each surrounded by the diffusion surface 610, and a holder 63 for holding the diffused illuminator 61. In FIGS. 6A and 6B, for distinction from the diffused illuminator 61, regions which correspond to the holder 63 are dotted.

The diffused illuminator 61 is made of a white resin, for example, PTFE (polytetrafluoroethylene). The diffused illuminator 61 has a plate shape substantially in parallel to a YZ plane, and has a cut 611 formed at an end part thereof on a (+Y) direction side. This cut 611 has a shape obtained by turning a U shape clockwise by 90° as viewed from a (+X) direction side.

In the diffused illuminator 61, inclined surfaces 610 are provided along the cut 611. The inclined surfaces 610 are so provided as to surround the cut 611 from upper and lower directions and a (−Y) direction, and each is a tapered surface which is so finished as to be inclined to a (−X) direction as it approaches the cut 611. The surface thereof is so finished as to diffusely reflect incident light and serves as the diffusion surface 610 for diffusely reflecting the illumination light to be incident on the peripheral edge part Ss of the substrate S, as described later.

The mirror members 62a to 62c are so attached as to be surrounded by the diffusion surfaces 610. More specifically, in the diffusion surfaces 610, the first mirror member 62a is attached at a position vertically above the cut 611, the second mirror member 62b is attached on the (−Y) side of the cut 611, and the third mirror member 62c is attached at a position vertically below the cut 611. Further, in the present embodiment, the mirror members 62a to 62c are made of Si (silicon) in consideration of chemical resistance, heat resistance, and the like.

On the other hand, the holder 63 is made of a resin having high resistance to a chemical liquid and heat, for example, PEEK (polyetheretherketone) and is a plate-like member whose outer shape is formed substantially like the diffused illuminator 61. The holder 63 is coupled to a rear surface of the diffused illuminator 61, i.e., a main surface on the (−X) side, to thereby serve as a backup member. Further, the holder 63 is coupled to the arm 6C. Therefore, with oscillation of the arm 6C, the diffused illuminator 61 and the holder 63 move as one unit between the retracted position P1 and the imaging position P2.

As shown in FIG. 6A, when the head unit 6G is positioned at the imaging position P2 and the substrate S is held by the spin chuck 21, the peripheral edge part Ss of the substrate S enters the cut 611. When the cut 611 is viewed from the (+X) side toward the (−X) direction, a portion of the peripheral edge part Ss of the substrate S, which can be seen as viewed from above, i.e., a figure of the A surface Sa and the B surface Sb is reflected in the first mirror member 62a. Similarly, a portion of the peripheral edge part Ss of the substrate S, which can be seen as viewed from side, i.e., a figure of the B surface Sb, the C surface Sc, and the D surface Sd is reflected in the second mirror member 62b. Further, a portion of the peripheral edge part Ss of the substrate S, which can be seen as viewed from below, i.e., a figure of the D surface Sd and the E surface Se is reflected in the third mirror member 62c.

As described later in detail, the observation optical system 6F performs imaging with an imaging field of view which is so set as to view all the three mirror members 62a to 62c from the (+X) side. The respective figures of the substrate S which are reflected in the mirror members 62a to 62c are captured in one image. In other words, the observation optical system 6F can collectively image all the A surface Sa, the B surface Sb, the C surface Sc, the D surface Sd, and the E surface Se of the substrate Ss to be captured into one image. By performing imaging a plurality of times with rotation of the substrate S, it is possible to acquire images of a plurality of regions in the peripheral edge part Ss, which are different in the position along the circumferential direction.

In the following description, the imaging of a figure of the A surface Sa and the B surface Sb of the substrate S, which is reflected in the first mirror member 62a, is referred to as “upper surface imaging”. Further, the imaging of a figure of the B surface Sb, the C surface Sc, and the D surface Sd of the substrate S, which is reflected in the second mirror member 62b, is referred to as “side surface imaging”. Furthermore, the imaging of a figure of the D surface Sd and the E surface Se of the substrate S, which is reflected in the third mirror member 62c, is referred to as “lower surface imaging”.

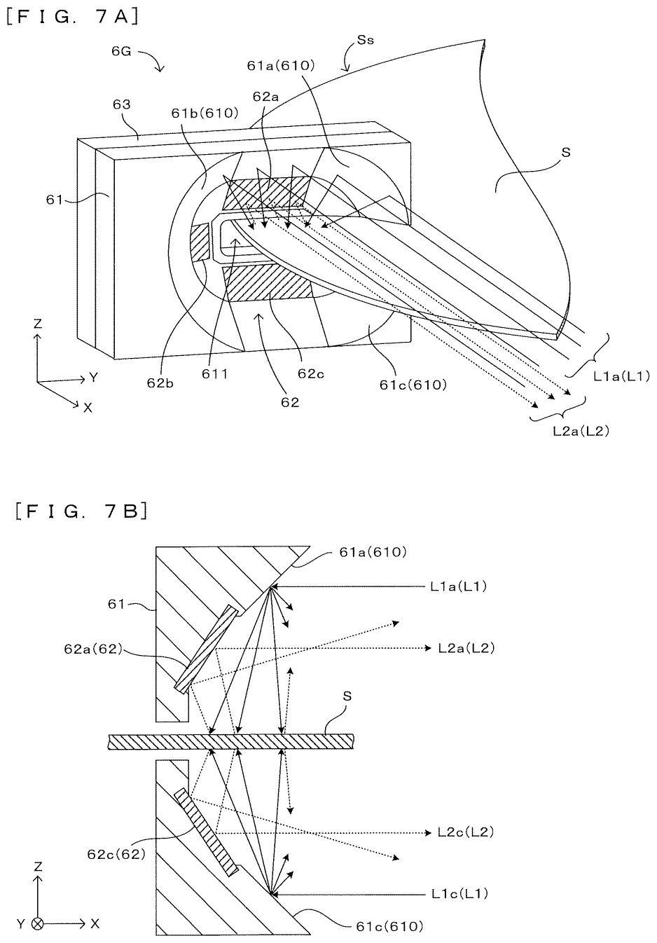

FIGS. 7A and 7B are views each schematically showing how light contributing to the upper surface imaging propagates. More specifically, FIG. 7A is a perspective view showing a path of the light which is incident and reflected on the head unit 6G, and FIG. 7B is a cross-sectional view at a vertical cross section of FIG. 7A. As indicated by solid-line arrows in FIGS. 7A and 7B, in the illumination light L1, illumination light L1a going in the (−X) direction along the upper surface side of the substrate S is incident on the diffusion surface 610 of the head unit 6G. The light which is incident on an upper diffusion surface 61a of the diffusion surface 610, particularly, which is positioned above the cut 611, and diffusely reflected thereon is incident on the upper surface of the substrate S from various directions, to thereby illuminate the peripheral edge part Ss of the substate S.

As indicated by dotted-line arrows, the reflected light reflected on the substrate S can go in various directions, but light L2a of the reflected light, which is incident on the mirror member 62a and reflected on the mirror member 62a to go in the (+X) direction, enters the observation optical system 6F disposed on the optical path. By receiving this light, the “upper surface imaging” for imaging the peripheral edge part Ss viewed from the upper surface side of the substrate S is achieved.

As shown in FIG. 7B, also on the lower surface side of the substrate S, the same phenomenon as that on the upper surface side occurs. Specifically, the head unit 6G has a vertically symmetrical structure, and illumination light L1c of the illumination light L1, which goes in the (−X) direction along the lower surface side of the substrate S, is incident and diffusely reflected on a lower diffusion surface 61c of the diffusion surface 610, particularly, which is positioned below the cut 611, to thereby illuminate the lower surface of the substrate S. At that time, by receiving reflected light L2c reflected on the substrate S and the mirror member 62c to go toward the (+X) direction, the “lower surface imaging” for imaging the peripheral edge part Ss viewed from the lower surface side of the substrate S is achieved.

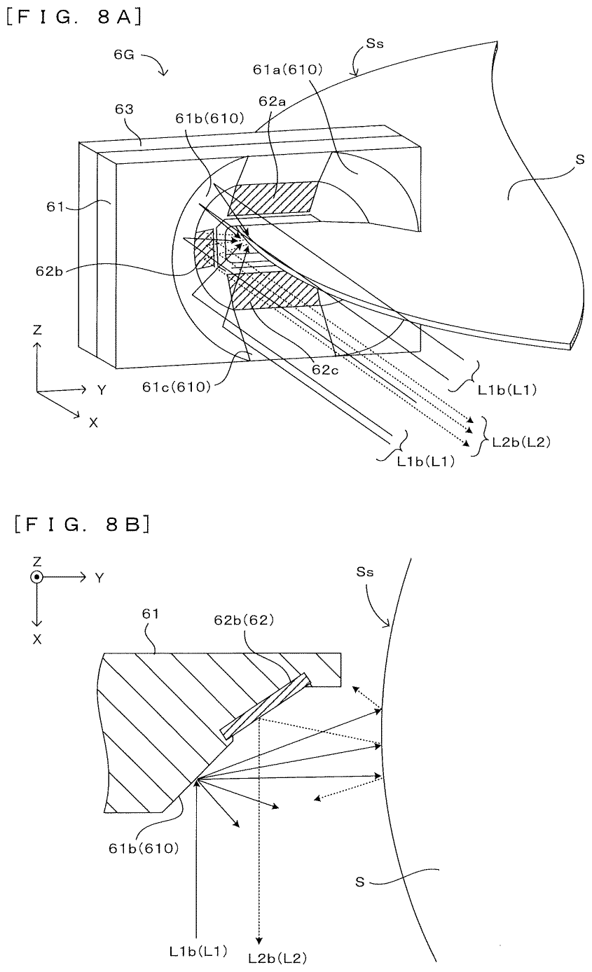

FIGS. 8A and 8B are views each schematically showing how light contributing to the side surface imaging propagates. More specifically, FIG. 8A is a perspective view showing a path of the light which is incident and reflected on the head unit 6G, and FIG. 8B is a cross-sectional view at a horizontal cross section of FIG. 8A. As indicated by solid-line arrows in FIGS. 8A and 8B, in the illumination light L1, illumination light L1b going in the (−X) direction along the side of the substrate S is incident on the diffusion surface 610 of the head unit 6G and diffusely reflected on a side diffusion surface 61b of the diffusion surface 610, particularly, which is positioned on the side of the cut 611. This light is incident on the side surface of the substrate S from various directions, to thereby illuminate the peripheral edge part Ss.

Then, in the reflected light reflected on the substrate S, as indicated by dotted-line arrows, light L2b which is reflected on the mirror member 62b to go in the (+X) direction enters the observation optical system 6F disposed on the optical path. The “side surface imaging” for imaging the peripheral edge part Ss viewed from the side of the substrate S is achieved.

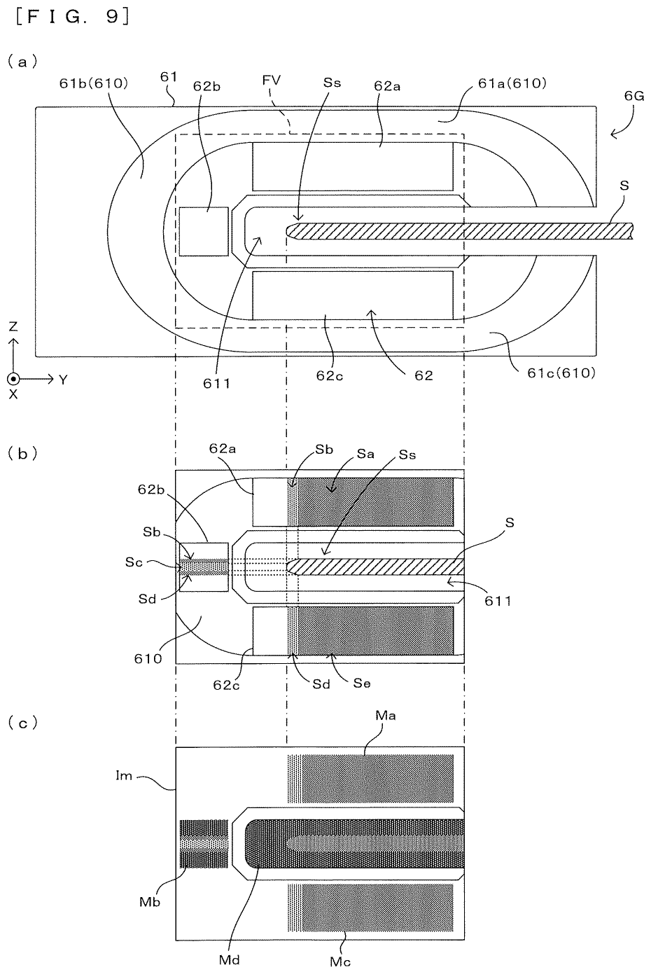

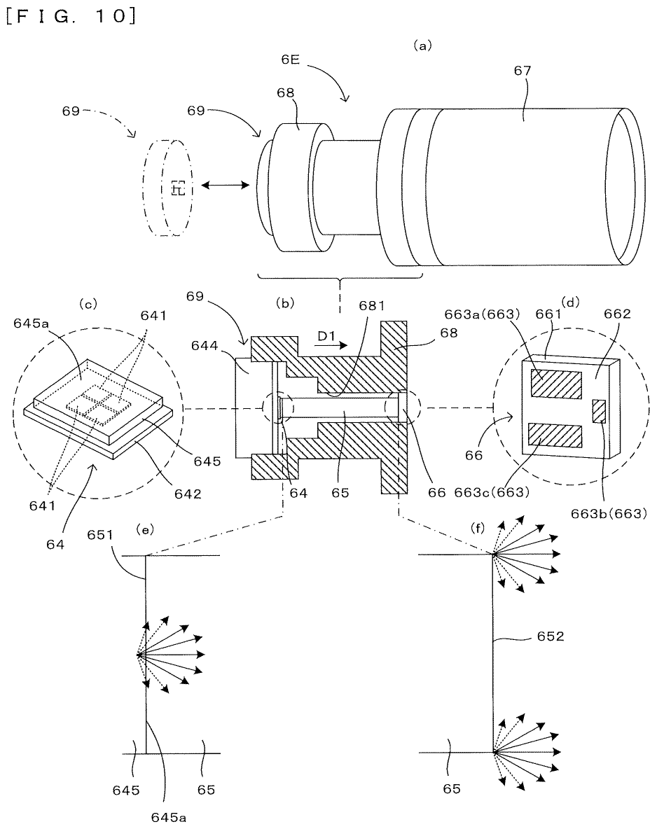

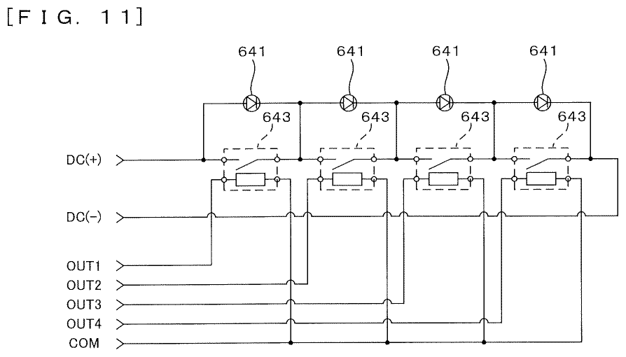

The observation optical system 6F has an observation lens system consisting of object-side telecentric lenses and for example, a CMOS camera. Therefore, in the above-described reflected light, only reflected light L2 (L2a, L2b, L2c) in parallel to the optical axis of the observation lens system enters a sensor surface of the CMOS camera, to thereby form an image of a figure of the peripheral edge part Ss of the substrate S and an adjacent region thereof on the sensor surface. Thus, the observation optical system 6F images the peripheral edge part Ss of the substrate S and the adjacent region thereof and acquires an image Im including an upper-surface image region Ma, a side-surface image region Mb, and a lower-surface image region Mc as shown in, for example, FIG. 9. Then, the observation optical system 6F sends image data representing the image to the control unit 9.

FIG. 9 is a chart schematically showing images of the peripheral edge part of the substrate captured by the imager. FIG. 9(a) is a schematic diagram showing the head unit 6G and the substrate S viewed from the (+X) side toward the (−X) direction, and a region FV surrounded by the broken line represents an imaging field of view of the observation optical system 6F. Thus, the imaging field of view FV of the observation optical system 6F is so set as to include the mirror members 62a to 62c in the head unit 6G.

FIG. 9(b) is a view schematically showing the figures of the substrate S reflected in the respective mirror members 62a to 62c in the imaging field of view FV. As shown in FIG. 9(b), in the first mirror member 62 a, reflected is the figure of the A surface Sa and the B surface Sb in the peripheral edge part Ss of the substrate S. Further, in the second mirror member 62b, reflected is the figure of the B surface Sb, the C surface Sc, and the D surface Sd in the peripheral edge part Ss of the substrate S. Furthermore, in the third mirror member 62c, reflected is the figure of the D surface Sd and the E surface Se in the peripheral edge part Ss of the substrate S. The observation optical system 6F collectively images these figures at the same time, to thereby acquire one image.

FIG. 9(c) is a view schematically showing the image which is actually acquired by the imaging. In the imaging mechanism 6 having the above-described configuration, the illumination light from the illumination optical system 6E is diffused by the diffusion surface 610, to thereby illuminate the substrate S, and by receiving part of the reflected light from the substrate S, imaging is performed. For this reason, neither the quantity of illumination light nor the quantity of received light is sufficient. In order to perform excellent imaging in such a condition, it is necessary to increase the sensitivity of a camera, and as a result, the detailed configuration of the head unit 6G is hardly reflected on any image due to so-called overexposure (blown-out highlights).

For this reason, as shown in FIG. 9(c), the image Im which is actually acquired includes a dark region Md which corresponds to the cut 611 and includes thereinside a figure of the side surface of the substrate S, which is reflected in an unfocused state, the upper-surface image region Ma which corresponds to a figure of the peripheral edge part Ss of the substrate S viewed from above, the side-surface image region Mb which corresponds to a figure of the peripheral edge part Ss of the substrate S viewed from side, and the lower-surface image region Mc which corresponds to a figure of the peripheral edge part Ss of the substrate S viewed from below.

By analyzing the image Im including these regions, information indicating the shape of the peripheral edge part of the substrate S in the circumferential direction, a state of etching, and the like can be acquired. Then, from these pieces of information, it is possible to inspect the eccentricity amount of the substrate S placed on the spin chuck 21 with respect to the axis of rotation AX, the warp amount of the substrate S, a bevel etching result (etching width), and the like.

Accordingly, in the substrate processing apparatus 1 equipped with the imaging mechanism 6 configured as described above, the control unit 9 controls each component of the apparatus to perform (A) substrate inspection before the bevel etching processing, (B) alignment processing, (C) bevel etching processing after the alignment processing, and (D) substrate inspection after the bevel etching processing. As shown in FIG. 5, this control unit 9 includes an arithmetic processor 91 for performing various types of arithmetic processing, a storage 92 for storing therein a basic program and image data, and an input/display unit 93 for displaying various pieces of information and receiving an input from an operator.

Then, in the control unit 9, the arithmetic processor (CPU) 91 serving as a main controller performs the arithmetic processing in accordance with a procedure described in the program, thereby controlling each component of the substrate processing apparatus 1 as follows. Specifically, as shown in FIG. 5, the arithmetic processor 91 functions as a positioning controller 911 for positioning the head unit 6G, an entire peripheral edge image acquirer 912 for acquiring an entire peripheral edge image, an eccentricity amount deriver 913 for deriving the eccentricity amount of the substrate S from the entire peripheral edge image before the bevel etching processing, a warp amount deriver 914 for deriving the warp amount of the substrate S from the entire peripheral edge image before the bevel etching processing, an etching width deriver 915 for deriving an etching width from the entire peripheral edge image after the bevel etching processing, and a residue analyzer 916 for analyzing residues from a residue enhanced image obtained by performing image processing on the entire peripheral edge image.

Further, reference numeral 7 in FIG. 5 denotes an eccentricity correcting mechanism for correcting the eccentricity of the substrate S with respect to the axis of rotation AX by moving the substrate S by the above-described eccentricity amount. Since a conventionally-known one can be used as the eccentricity correcting mechanism, the detailed configuration of the eccentricity correcting mechanism 7 will not be described herein.

The illumination optical system 6E of the above-described imaging mechanism 6 irradiates the region Fv (see FIG. 9(a)) including the diffusion surface 610 with the illumination light L1 as primary illumination light, to thereby generate diffused light which is diffusely reflected on the diffusion surface 610, as secondary illumination light. Then, the substrate S is illuminated by the diffused light (illuminating process (step)). Further, the observation optical system 6F of the above-described imaging mechanism 6 receives part of the reflected light from the substrate S, to thereby image the peripheral edge part Ss of the substrate S. Thus, the peripheral edge part Ss is observed by the observation optical system 6F (observing process (step)). Thus, the peripheral edge part Ss of the substrate S is observed by using the imaging mechanism 6, and the substrate S and the peripheral edge part Ss correspond to one example of an “observation target” and one example of an “observation target part” of the present invention, respectively, and the imaging mechanism 6 corresponds to one example of an “observation apparatus” of the present invention.

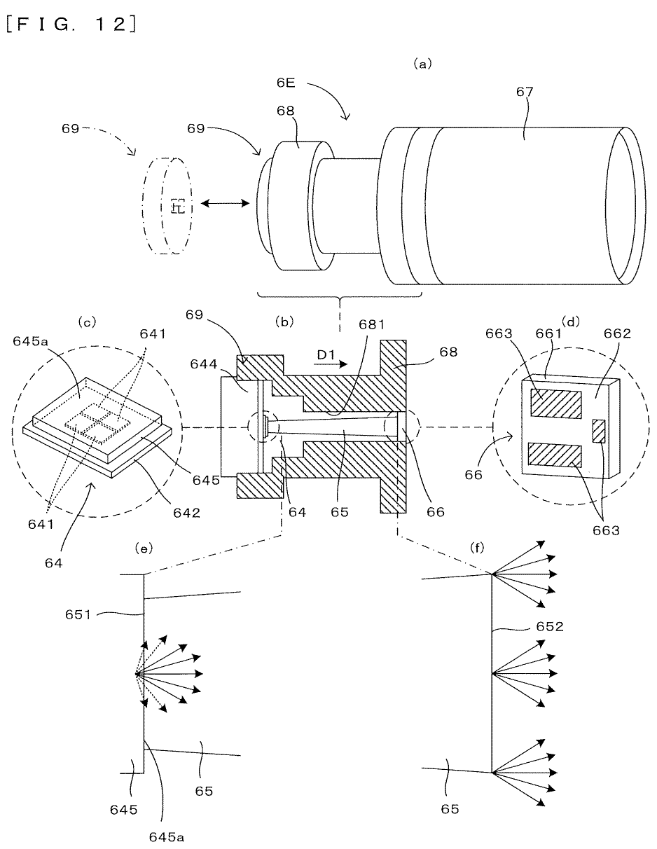

In order to satisfactorily acquire the image of the peripheral edge part Ss by the imaging mechanism 6, the following point is requested for the observation optical system 6F. Specifically, the light quantity distribution of the diffused light (secondary illumination light) to be emitted to the peripheral edge part Ss should be uniform. Then, the imaging mechanism 6 having a configuration shown in FIG. 10 is used in the substrate processing apparatus 1 and corresponds to a first embodiment of the observation apparatus in accordance with the present invention.

FIG. 10 is a diagram showing one example of the illumination optical system provided in the substrate processing apparatus in accordance with the present invention. FIG. 10(a) shows an overall configuration of the illumination optical system, and FIG. 10(b) shows a cross section of a configuration excluding a projection optical part from the illumination optical system 6E. The illumination optical system 6E has a light source part 64, an optical rod 65, a mask part 66, and a projection optical part 67. The light source part 64, the optical rod 65, and the mask part 66 are positioned and held by a light-emitting side package 68. Then, the light-emitting side package 68 and the projection optical part 67 are coupled to each other.

In the light-emitting side package 68, a through hole 681 is extended. The light source part 64 and the mask part 66 are attached to both end parts of the light-emitting side package 68, respectively, in an extending direction D1 (the left-and-right direction of the paper in FIG. 10) of the through hole 681. Further, inside the through hole 681, the optical rod 65 is disposed in parallel to the above-described extending direction D1 and fixed by a not-shown rod holder. The optical rod 65 is formed of glass or a resin material having transparency to the light beams going out from the light source part 64 and has a columnar shape extending in a direction parallel to the extending direction D1.

As shown in FIG. 10(c), the light source part 64 has one or a plurality of light emitting elements 641 and a light source substrate 642 on which the light emitting elements 641 are mounted. In the present embodiment, four light emitting elements 641 are provided in a matrix.

FIG. 11 is a diagram showing one example of a drive circuit of the light emitting elements. As shown in this figure, the four light emitting elements 641 are connected in series to a DC power supply. Further, a semiconductor relay 643 is provided for each light emitting element 641 and controls lighting of the corresponding light emitting element 641 in response to each of signals OUT1 to OUT4 from the control unit 9. Herein, in a case where the light emitting elements 641 are the same, by the above-described lighting control, it is possible to adjust the quantity of light of the light beams emitted from the light source part 64. Furthermore, in a case where the four light emitting elements 641 emit the light beams having different wavelengths, by the above-described lighting control, it is possible to adjust the quantity of light and the color of the light beams emitted from the light source part 64.

Back to FIG. 10, description will continue. In order to efficiently dissipate the heat generated in the lighting of the light emitting element 641, as shown in FIGS. 10(a) and 10(b), a heat dissipation member 644 formed of aluminum is attached on the opposite side (the left-hand side in FIG. 10) to the light emitting elements of the light source substrate 642. Further, in the present embodiment, by unifying the light emitting elements 641, the light source substrate 642, and the heat dissipation member 644, a light emitting structure 69 is formed. Moreover, the light emitting structure 69 is attachable and detachable to/from the light-emitting side package 68. The light emitting structure 69 may be changed to a new one, for example, in accordance with the lifetime of the light emitting elements 641. Further, there may be a configuration where the light emitting structures 69 having combinations of the light emitting elements 641, which are different from one another in the luminescent color, the number thereof, and/or the like, are prepared in advance and a light emitting structure 69 is selectively attached in accordance with the type of the substrate S to be processed, or the like.

As shown in FIG. 10(c), on the light emitting element side of the light source substrate 642, a protective cover 645 is so provided as to cover the light emitting elements 641. The protective cover 645 is formed of glass or a resin material having transparency to the light beams emitted from the light emitting elements 641, and an end surface 645a thereof on the optical rod side is finished to be a flat surface. This end surface 645a is in close contact with an end surface 651 of the optical rod 65 while facing it. Therefore, when the light emitting elements 641 light up to emit the light beams, as shown in FIG. 10(e), the light beams emitted from the light emitting elements 641 with a certain spread enter the optical rod 65 through the protective cover 645.

The cross section of the optical rod 65 has a circular shape or a polygonal shape, and the end surface 651 on the side of the light source part corresponds to an incident end and an end surface 652 on the side of the projection optical part corresponds to an outgoing end. Specifically, in the optical rod 65, when the light beams emitted from the light source part 64 are incident from the end surface 651, except part of the light beams (light beams indicated by the dotted lines in FIG. 10(e)), a lot of light beams are propagated in the extending direction D1 while being totally reflected inside the optical rod 65. Then, as shown in FIG. 10(f), the light beams having almost the same characteristics are emitted from portions of the end surface 652, as the above-described primary illumination light L1. For this reason, the light quantity distribution of the light beams in the end surface 652 has a top hat shape. In other words, the optical rod 65 performs a beam homogenizer function, and as a result, the primary illumination light L1 having a uniform light quantity distribution is acquired.

Herein, by configuring the projection optical part 67 to perform projection on the diffusion surfaces 610 by enlarging the outgoing end (the end surface 652) of the optical rod 65 with appropriate magnification, it is possible to perform primary lighting on the diffusion surfaces 610 with uniform light quantity distribution. Further, as described above, by lighting all the light emitting elements 641 in response to the signals OUT1 to OUT4 (FIG. 11) from the control unit 9, it is possible to irradiate the diffusion surfaces 610 with the primary illumination light L1 having a relatively large quantity of light. It is thereby possible to increase the quantity of light of the diffused light (secondary illumination light) and excellently observe the peripheral edge part Ss of the substrate S. Further, it is possible to illuminate the peripheral edge part Ss of the substrate S with a color suitable for the observation of the peripheral edge part Ss.

In a case, for example, of observing the pattern-formed substrate S, however, such a problem as described below sometimes arises. When the outgoing end (the end surface 652) of the optical rod 65 is projected as it is onto the head unit 6G by the projection optical part 67 as described above, all the light beams going out from the optical rod 65, as the primary illumination light, are emitted onto not only the diffusion surfaces 610 but also the mirror members 62a to 62c. Sometimes, the light specularly reflected on the mirror members 62a to 62c is incident to the substrate S with high intensity and further specularly reflected on the substrate S to be incident onto the diffusion surfaces 610. This sometimes generates new diffused light to cause a diffraction phenomenon of the light on the pattern of the substrate S. Further, the light incident to the substrate S with high intensity as described above sometimes goes back to the mirror members 62a to 62c to be incident to the observation optical system 6F. By these factors, a bright portion which does not originally exist is observed, and this causes a reduction in the observation quality.

Then, in the present embodiment, the mask part 66 shown in FIG. 10(b) and 10(d) is interposed between the optical rod 65 and the projection optical part 67. The mask part 66 has a flat plate 661 formed of glass or a resin material having transparency to the primary illumination light L1. Among both main surfaces of this flat plate 661, a main surface 662 facing the optical rod 65 is provided with three masks 663. These masks 663 are in optical conjugation with the mirror members 62a to 62c and serve as light shielding masks for the mirror members 62a to 62c, respectively. Specifically, the respective masks 663 block out the light beams incident from the end surface 652 of the optical rod 65 and regulates emission of the primary illumination light L1 to the mirror members 62a to 62c. As a result, the above-described problem is solved. On the other hand, the diffusion surface 610 is irradiated with the primary illumination light L1 passing through an unmasked region of the mask part 66. As a result, it is possible to observe the peripheral edge part Ss of the substrate S with excellent quality while the above-described problem is solved.

As described above, in the present embodiment, the optical rod 65 corresponds to one example of a “beam homogenizer” of the present invention. The protective cover 645 and the end surface 645a correspond to one example of a “cover” and one example of a “flat surface” of the present invention, respectively.

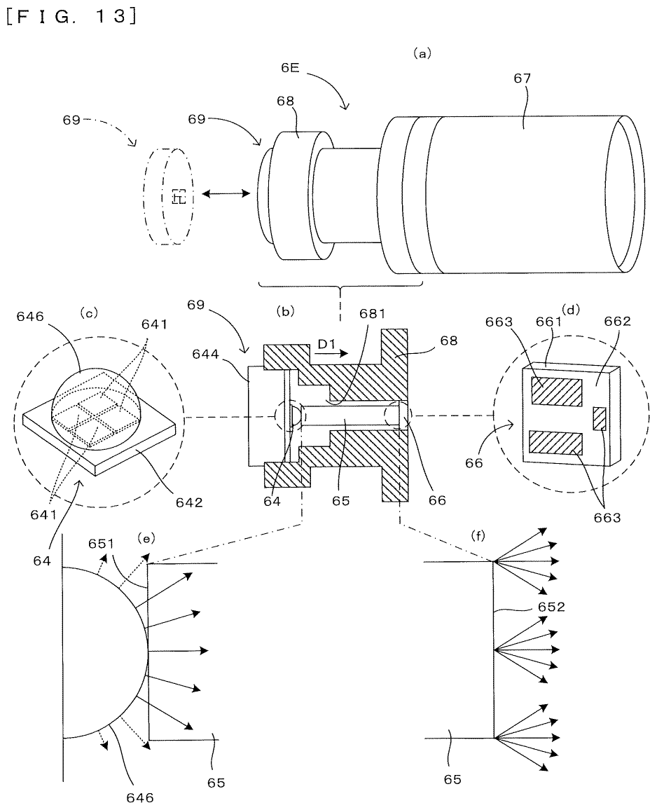

FIG. 12 is a diagram showing another example of the illumination optical system provided in the substrate processing apparatus in accordance with the present invention. This illumination optical system 6E is provided in a second embodiment of the observation apparatus in accordance with the present invention. The second embodiment is different from the first embodiment largely in that a tapered-shaped optical rod 65 is used, instead of the cylindrical or polygonal prism-like optical rod 65. More specifically, as shown in FIG. 12(b), the optical rod 65 is formed of a tapered rod whose cross-sectional area becomes larger as it goes from the incident end 651 toward the outgoing end 652. Further, the constituent elements other than the above in the second embodiment are identical to those in the first embodiment, and are therefore represented by the same reference signs and will not be described.

In this second embodiment, as can be seen from the comparison between FIG. 10(f) and 12(f), since the optical rod 65 has the above-described tapered shape, a divergence angle of the light beams going out from the end surface 652 of the optical rod 65, i.e., the outgoing end becomes smaller than that in the first embodiment. It thereby becomes easier to take all the light beams going out from the optical rod 65 into the projection optical part 67. As a result, the degree of design freedom of the projection optical part 67 is higher than that in the first embodiment, and moreover the projection performance can be kept high.

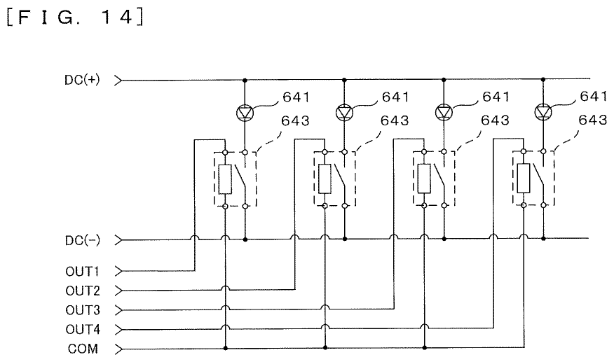

FIG. 13 is a diagram showing still another example of the illumination optical system provided in the substrate processing apparatus in accordance with the present invention. This illumination optical system 6E is provided in a third embodiment of the observation apparatus in accordance with the present invention. The third embodiment is different from the first embodiment largely in that a dome lens 646 is provided therein. This dome lens 646 has a dome-shaped surface protruding toward the optical rod side and is so provided as to cover all the light emitting elements 641 from the optical rod side. For this reason, by the lens effect of the dome lens 646, most of the light beams emitted from the light emitting elements 641 are guided to the end surface 651 of the optical rod 65, i.e., the incident end to be incident to the optical rod 65 at a low divergence angle (part of the light beams are not incident to the optical rod 65, however, as indicated by the dotted lines in FIG. 13(e)). For this reason, it is possible to shorten the optical rod 65 in the direction D1 and reduce the working distance of the illumination optical system 6E as compared with those in the first embodiment.

Though respective technical features of the above-described three types of illumination optical systems 6E are different from one another, these illumination optical systems 6E have such common action and effect as to uniformize the light quantity distribution of the primary illumination light L emitted on the diffusion surface 610 and thereby observe the peripheral edge part Ss of the substrate S with excellent quality. Therefore, depending on the technical demand in incorporating the imaging mechanism 6 into the substrate processing apparatus 1, any one of the first embodiment, the second embodiment, and the third embodiment can be selected.

Further, the present invention is not limited to the above-described embodiments and numerous modifications and variations can be added to those described above without departing from the scope of the invention. Though the four light emitting elements 461 are used in the embodiments, for example, the number of light emitting elements 461 is not limited to “4” but may be arbitrarily determined. The present invention may be configured, for example, to emit the light beams from a single light emitting element having a relatively wide light-emitting surface. As a matter of course, the present invention may be configured to emit the light beams from two, three, five, or more light emitting elements 461.

Furthermore, in a case of using a plurality of light emitting elements 641, like in the first to third embodiments, these light emitting elements 641 may be connected in series to perform light emission. Further, as shown in FIG. 16, there may be a configuration, for example, where the four light emitting elements 641 are connected in parallel and lighting control of the light emitting elements 641 is performed by individually switching open/close of the semiconductor relays 643 in response to the signals OUT1 to OUT4 from the control unit 9, and the same action and effect as those of the first embodiment can be produced. Moreover, if the parallel connection structure is adopted, for example, even when one of the light emitting elements 641 has broken down, the remaining light emitting elements 641 can continue to light up and continuously perform observation processing. Furthermore, when the above-described breakdown occurs, the current whose amount is larger than that before the breakdown is carried in the remaining light emitting elements 641 and it is possible to suppress the reduction in the quantity of light. Thus, the parallel connection structure has excellent robustness.

Further, as to the connection structure of the light emitting elements 641, both the series connection and the parallel connection may be used. In a case, for example, where the four light emitting elements 641 constitute the light source part 64, two light emitting element rows in which the two light emitting elements 641 are connected in series are formed and these two emitting element rows may be connected in parallel.

Furthermore, though the mask part 66 is provided in consideration of the observation of the pattern-formed substrate S in the above-described embodiments, it is not necessary to provide any mask part 66 in the substrate processing apparatus 1 not requiring the above-described consideration.

Further, though the optical rod 65 is used as the “beam homogenizer” for uniformizing the light quantity of the light beams from the light source part 64 in the above-described embodiments, any other beam homogenizer may be used.

Furthermore, though the respective lengths of in the Y direction of the upper diffusion surface 61a, the lower diffusion surface 61c, and the mirror members 62a and 62c are set corresponding to the bevel etching width of the substrate S in the embodiments, the respective lengths of these components may be changed in accordance with a range to be observed by the imaging mechanism 6. Further, there may be a configuration where head units 6G are prepared, having the diffusion surfaces and the mirror members with the respective lengths in the Y direction different from one another and a head unit 6G is selectively used in accordance with a range to be imaged. Furthermore, in a case where the head units 6G are prepared, having the diffusion surfaces with the respective lengths in the Y direction different from one another, the diffusion surface of the head unit 6G may be formed of a continuous curved plane. Further, in the case where the head units 6G are prepared, having the diffusion surfaces with the respective lengths in the Y direction different from one another, part of the diffusion surface of the head unit 6G may be formed of a flat plane.

Further, though the observation lens system of the observation optical system 6F is constituted of the object-side telecentric lenses in the above-described embodiments, the configuration of the observation lens system of the observation optical system 6F is not limited to this. The observation lens system of the observation optical system 6F may be constituted of any other lenses.

Furthermore, though the above-described embodiments each have a configuration where the reflected light L2 reflected on the peripheral edge part Ss of the substrate S goes through the above-described mirror members 62a to 62c to be received by the observation optical system 6F, these embodiments may each have another configuration where the reflected light L2 is received by the observation optical system 6F.

Further, in the above-described embodiments, since the diffused illuminator 61 and the holder 63 are disposed under an environment of the processing liquid used for performing the bevel etching processing and an environment that is heated by the heater 51, the diffused illuminator 61 and the holder 63 are formed of materials having chemical resistance and heat resistance. Though the diffused illuminator 61 and the holder 63 are formed of PTFE and PEEK, respectively, the constituent materials are not limited to these. The diffused illuminator 61 may be formed of a material having chemical resistance and heat resistance, other than PTFE. The holder 63 may be formed of a material having chemical resistance and heat resistance, other than PEEK. The diffused illuminator 61 and the holder 63 may be formed of, for example, a metal material, a resin material, or a material obtained by coating a surface of a ceramic material or the like with a fluororesin material such as PFA or the like. Furthermore, though the diffused illuminator 61 and the holder 63 are formed of different materials, the diffused illuminator 61 and the holder 63 may be formed of the same material. Further, in a case where the diffused illuminator 61 and the holder 63 are used under an environment requiring neither chemical resistance nor heat resistance, the constituent materials thereof are not limited. The diffused illuminator 61 and the holder 63 may be formed of materials having neither chemical resistance nor heat resistance.

Further, the respective constitutions of the diffusion surfaces 61a to 61c of the diffused illuminator 61 and the holder 63 are not limited to the above. In a case, for example, where at least part of the diffused illuminator 61 and the holder 63 is formed of a metal material, the diffusion surfaces 61a to 61c may be formed by shot-blasting a surface of the metal material.

Furthermore, the material of the mirror members 62a to 62c is also not limited to Si (silicon). Specifically, any other material may be used only if the material is chemical resistant against the processing liquid and heat resistant against a processing temperature. The mirror members 62a to 62c may be formed by, for example, evaporating a metal material on a surface of the material having chemical resistance and heat resistance. Further, in a case where the mirror members 62a to 62c are used under an environment requiring neither chemical resistance nor heat resistance, the constituent material thereof is not limited. The mirror members 62a to 62c may be formed of a material which is neither chemical resistant nor heat resistant. The mirror members 62a to 62c may be formed by, for example, evaporating a metal material on a surface of the material having neither chemical resistance nor heat resistance.

Further, though imaging of the peripheral edge part is performed by moving the substrate S which is an observation target while fixedly arranging the imaging mechanism 6 in the above-described embodiments, the present invention may be configured to move the imaging mechanism 6 while fixing the substrate S. Furthermore, both the substrate S and the imaging mechanism 6 may be moved. Specifically, there may be a configuration where the peripheral edge part of the observation target (substrate S) is imaged by the observation apparatus (imaging mechanism 6) while the observation target is moved relative to the observation apparatus.

Further, though the imaging mechanism 6 which corresponds to the observation apparatus in accordance with the present invention is incorporated into the substrate processing apparatus 1 which performs bevel etching processing on the peripheral edge part Ss of the substrate S in the above-described embodiments, the application target of the observation apparatus (imaging mechanism 6) is not limited to this. The present invention can be applied to an observation apparatus which images the observation target part of the observation target, and the like. Furthermore, the imaging mechanism 6 which corresponds to the observation apparatus in accordance with the present invention can be applied to a substrate processing apparatus which supplies the peripheral edge part of the substrate S on which a coating film is formed, with a removal liquid for the coating film, to remove the coating film from the peripheral edge part of the substrate S. Further, the imaging mechanism 6 can be applied to an observation apparatus which observes a surface of the substrate before performing exposure processing.

Although the invention has been described by way of the specific embodiments above, this description is not intended to be interpreted in a limited sense. By referring to the description of the invention, various modifications of the disclosed embodiments will become apparent to a person skilled in this art similarly to other embodiments of the invention. Hence, appended claims are thought to include these modifications and embodiments without departing from the true scope of the invention.

### INDUSTRIAL APPLICABILITY

This invention can be applied to an observation technique for observing an observation target such as a semiconductor wafer or the like and a substrate processing apparatus in general using the observation technique.

### REFERENCE SIGNS LIST

1 substrate processing apparatus
6 imaging mechanism (observation apparatus)
6E illumination optical system
6F observation optical system
6G head unit
610 diffusion surface
62a-62c mirror member
64 light source part
65 optical rod (beam homogenizer)
66 mask part
67 projection optical part
610 diffusion surface
641 light emitting element
642 light source substrate
645 protective cover
646 dome lens
651 incident end surface (of optical rod)
652 outgoing end surface (of optical rod)
663 mask
681 through hole
L1 primary illumination light
L2 reflected light
S substrate (observation target)
Ss peripheral edge part (observation target part)

1. An observation apparatus for observing an observation target part of an observation target, comprising:
an illumination optical system configured to emit primary illumination light to the vicinity of the observation target part;
a head unit having a diffusion surface which diffuses the primary illumination light in the vicinity of the observation target part and being configured to illuminate the observation target part by irradiating the observation target part with diffused light generated on the diffusion surface as secondary illumination light; and
a camera configured to receive reflected light reflected on the observation target part illuminated with the secondary illumination light to observe the observation target part,
wherein the illumination optical system has:
a beam homogenizer having an incident end and an outgoing end;
a light source part having a light emitting element that is configured to cause light beams forming the primary illumination light to be incident to the incident end of the beam homogenizer; and
a projection optical part configured to project the outgoing end of the beam homogenizer onto the diffusion surface.

2. The observation apparatus according to claim 1, wherein
the beam homogenizer is an optical rod formed of a material having transparency to the light beams.

3. The observation apparatus according to claim 2, wherein
the light source part further has:
a light source substrate on which the light emitting element is mounted; and
a protective cover provided so as to cover the light emitting element from the side of the beam homogenizer, the protective cover being configured to emit the light beams from a flat surface on the side of the beam homogenizer.

4. The observation apparatus according to claim 3, wherein
the optical rod is a tapered rod whose cross-sectional area becomes larger as it goes from the incident end toward the outgoing end.

5. The observation apparatus according to claim 2, wherein
the light source part further has:
a light source substrate on which the light emitting element is mounted; and
a dome lens provided so as to cover the light emitting element from the side of the beam homogenizer, the dome lens configured to emit the light beams from a dome-shaped surface protruding toward the side of the beam homogenizer.

6. The observation apparatus according to claim 1, wherein
the light source part includes the plurality of light emitting elements that are connected in parallel with each other.

7. The observation apparatus according to claim 1, wherein
the light source part includes a plurality of light emitting element rows, each of which are formed by connecting the plurality of light emitting elements in series, the plurality of light emitting element rows being connected in parallel with each other.

8. The observation apparatus according to claim 1, wherein
the head unit has a mirror member configured to reflect thereon the reflected light and guide the reflected light to the observation optical system.

9. The observation apparatus according to claim 8, further comprising:
a mask part disposed at the outgoing end of the beam homogenizer, the mask part being configured to selectively block out the light beams going toward the mirror member out of the primary illumination light.

10. An observation method for observing an observation target part of an observation target, comprising:
(a) illuminating the observation target part by emitting primary illumination light to a diffusion surface of a head unit positioned in the vicinity of the observation target part to thereby irradiate the observation target part with diffused light generated on the diffusion surface, as secondary illumination light; and
(b) observing the observation target part by receiving reflected light reflected on the observation target part illuminated with the secondary illumination light,
wherein the step (a) has:
causing light beams forming the primary illumination light to be incident to a beam homogenizer; and
projecting an outgoing end of the beam homogenizer onto the diffusion surface.

11. A substrate processing apparatus, comprising:
a spin chuck configured to hold and rotate a substrate;
a processing liquid nozzle configured to process a peripheral edge part of the substrate rotated by the rotating mechanism by supplying a processing liquid to the peripheral edge part of the substrate; and
an observation apparatus configured to observe the peripheral edge part before or after processing the peripheral edge part,
wherein the observation apparatus comprises:
an illumination optical system configured to emit primary illumination light to the vicinity of the observation target part;
a head unit having a diffusion surface which diffuses the primary illumination light in the vicinity of the observation target part and being configured to illuminate the observation target part by irradiating the observation target part with diffused light generated on the diffusion surface as secondary illumination light; and
a camera configured to receive reflected light reflected on the observation target part illuminated with the secondary illumination light to observe the observation target part,
wherein the illumination optical system has:
a beam homogenizer having an incident end and an outgoing end;
a light source part having a light emitting element that is configured to cause light beams forming the primary illumination light to be incident to the incident end of the beam homogenizer; and
a projection optical part configured to project the outgoing end of the beam homogenizer onto the diffusion surface.
